(19) United States
(12) Patent Application Publication
(10) Pub. No.: US 2006/0215364 A1
(43) Pub. Date: Sep. 28, 2006

(54) Heatsink for high-power microprocessors

(76) Inventor: Cuong Duy Le, Gilroy, CA (US)

Correspondence Address: THE MAXHAM FIRM, 750 "B" STREET, SUITE 3100, SAN DIEGO, CA, 92101, US

(21) Appl. No.: 11/091,538

(22) Filed: Mar. 28, 2005

(51) Int. Cl. H05K 7/20

(52) U.S. Cl. 361/695

(57) ABSTRACT

A heatsink for removing heat from a heat source such as an integrated circuit, a power supply, or a microprocessor. The heatsink includes a base having an airflow passage. The base is also adapted to contact at least a portion of the heat source. The heatsink further includes a pad placed in thermal contact with the base. The pad is configured with an array of individual conduits positioned over the airflow passage of the heatsink base. The array of individual conduits permit air to flow from the airflow passage, through the array of conduits.

### BACKGROUND OF THE INVENTION

1. Field of the Invention

The present invention relates generally to a heatsink, and in particular to a heatsink having an array of conduits which are cooled using natural convective forces.

2. Discussion of the Related Art

Electronic components, such as integrated circuits, are increasingly being used in different devices. One prevalent example of a device using integrated circuits is the computer. The central processing unit of most computers, including personal computers, is typically constructed from a plurality of integrated circuits. Integrated circuits are also used in other computer circuitry.

During normal operation, many electronic components, such as integrated circuits, generate significant amounts of heat. If this heat is not continuously removed, the electronic component may overheat, resulting in damage to the component or a reduction in its operating performance. For example, an electronic component may encounter thermal runaway, which may damage the electronic component. In order to avoid such problems caused by overheating, cooling devices are often used in conjunction with electronic components.

Over the years, the amount of heat generated by electronic components has increased. In addition, the size of electronic devices using these components has generally decreased, resulting in greater amounts of heat being generated within smaller confines. In order to adequately cool these hotter electronic devices within increasingly smaller areas, more efficient cooling devices are required.

One such cooling device used in conjunction with electronic components is a heatsink. A heatsink is a device that draws heat from a heat generating component and convects the heat to the surrounding atmosphere. The heatsink is typically formed from a thermally conductive material, such as aluminum or copper. The heatsink is usually placed on top of, and in physical contact with, the heat generating electronic component. In addition, a thermally conductive compound is typically placed between the electronic component and the heatsink to enhance the thermal conductivity between the electronic component and the heatsink. This thermal conductivity results in a substantial portion of the heat generated by the electronic component being conducted into the heat sink and away from the electronic component. The heat initially transfers to the surface of the heatsink where it is then convected into the surrounding atmosphere.

One method of increasing the cooling capacity of heat sinks is by including a plurality of cooling fins attached to the heat sink and a cooling fan that forces air past the cooling fins. The cooling fins serve to increase the surface area of the heat sink and, thus, increase the convection of heat from the heatsink to the surrounding atmosphere. Generally, the fan forces air past the fins, which further increases the convection of heat from the heat sink to the surrounding atmosphere. While such methods have enjoyed a measure of success, smaller and more efficient heatsinks are needed to keep pace with the increasingly smaller environments in which they operate.

### SUMMARY OF THE INVENTION

A heatsink for removing heat from a heat source such as an integrated circuit, a power supply, or a microprocessor. The heatsink includes a base having an airflow passage. The base is also adapted to contact at least a portion of the heat source. The heatsink further includes a pad placed in thermal contact with the base. The pad is configured with an array of individual conduits positioned over the airflow passage of the heatsink base. The array of individual conduits permit air to flow from the airflow passage, through the array of conduits.

### BRIEF DESCRIPTION OF THE DRAWING

The above and other aspects, features, and advantages of the present invention will become more apparent upon consideration of the following description of preferred embodiments, taken in conjunction with the accompanying drawing figures, wherein:

FIGS. 1 and 2 show perspective and exploded perspective views, respectively, of a heatsink in accordance with an embodiment of the present invention;

FIG. 3 is a top-view of the lower plate and conduit array of the heatsink pad of FIG. 1;

FIG. 4 is a top-view of the heatsink base of FIG. 1;

FIG. 5 is a partial side-view of the heatsink base of FIG. 1;

FIG. 6 is a top-view of an individual conduit which may be implemented as part of a conduit array;

FIG. 7 is a partial cross-sectional view of the heatsink pad of FIG. 1, showing several conduits of the conduit array;

FIG. 8 is a partial cross-sectional view of a heatsink pad in accordance with an alternative embodiment of the present invention;

FIG. 9 is a side-view of a heatsink in accordance with an alternative embodiment of the present invention; and

FIG. 10 is a side-view of the heatsink of FIG. 1 cooling a heat generating device.

### DETAILED DESCRIPTION OF PREFERRED EMBODIMENTS

In the following detailed description, reference is made to the accompanying drawing figures which form a part hereof, and which show by way of illustration specific embodiments of the invention. It is to be understood by those of ordinary skill in this technological field that other embodiments may be utilized, and structural, electrical, as well as procedural changes may be made without departing from the scope of the present invention. As a matter of convenience, various components of a heatsink will be described using exemplary materials, sizes, shapes, and dimensions. However, the present invention is not limited to the stated examples and other configurations are possible and within the teachings of the present disclosure.

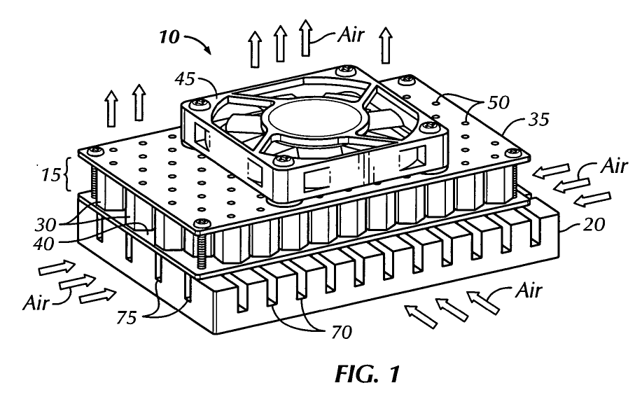

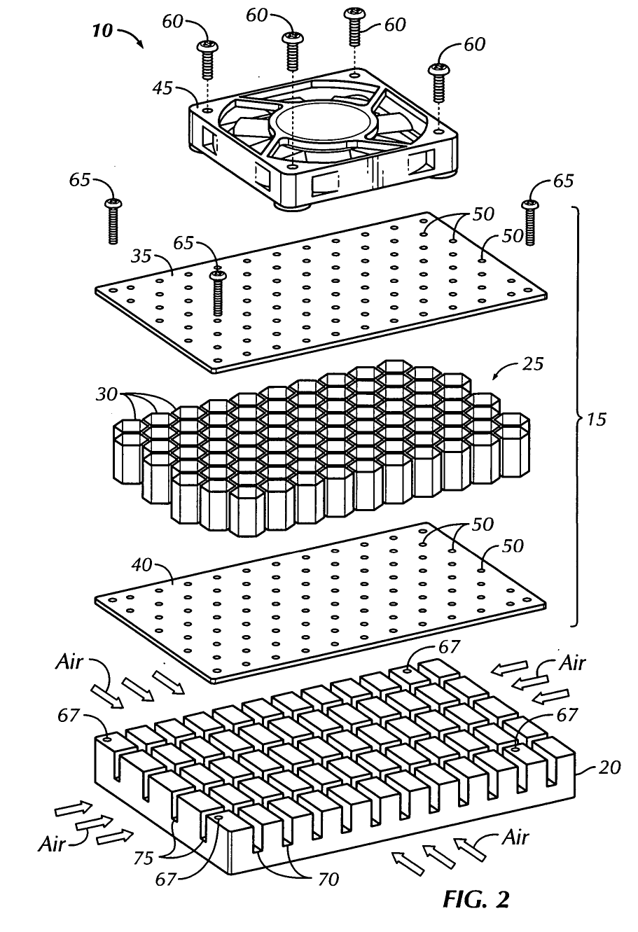

FIGS. 1 and 2 show perspective and exploded perspective views, respectively, of heatsink 10. The heatsink may be used to cool a heat generating device (not shown in this figure) and includes pad 15 and base 20. The pad includes conduit array 25, which is composed of individual hexagonal conduits 30 positioned between upper plate 35 and lower plate 40. Optional fan 45 is shown attached to the upper plate.

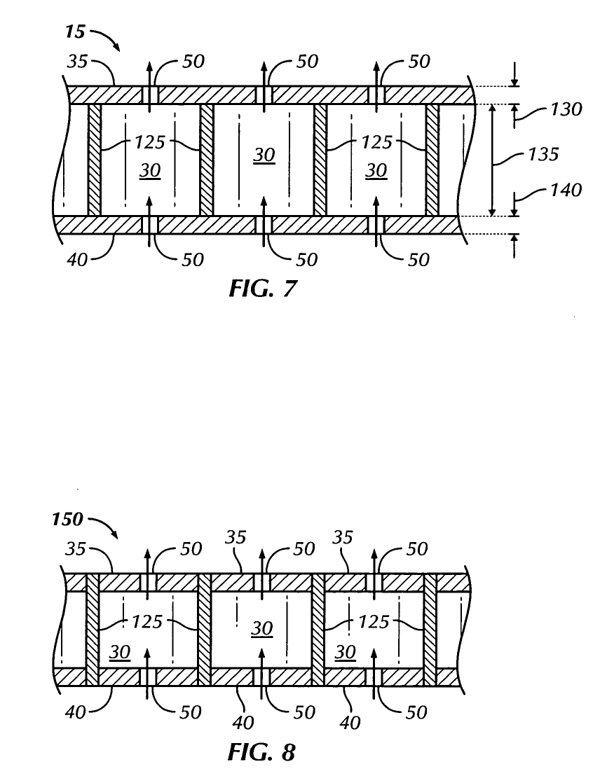

Both the upper and lower plates include an array of apertures 50 which are individually associated with particular conduits. Specifically, each aperture 50 formed in upper plate 35 may be positioned so that it generally coincides with a separate conduit 30 of the conduit array. Lower plate 40 may be similarly configured such that each aperture 50 formed in the lower plate generally coincides with a separate conduit 30. The relative spatial relationship between the conduits and the apertures of the upper and lower plates is more clearly visible in FIGS. 3 and 7.

In general, base 20 may be structured to include one or more airflow passages, channels, conduits, or other pathways, which permit air to flow from the surrounding atmosphere and into apertures 50 of lower plate 40. In the embodiment of FIGS. 1 and 2, base 20 includes a number of length-wise channels 75 and width-wise channels 70. The channels may be sized and arranged so that each aperture 50 of lower plate 40 is located over a portion of one or more of these channels.

If desired, the number of channels may be increased from that shown to effectively form a number of cooling fins. This may result in each aperture 50 of the lower plate being positioned over a plurality of such channels or cooling fins. Alternatively or additionally, either the length-wise channels or the width-wise channels may be omitted, as long as the apertures of lower plate 40 are able to receive and direct air into their associated conduits.

The various structural components of pad 15 and base 20 may be formed from a thermally conductive material such as aluminum, copper, copper-tungsten alloy, aluminum nitride, and beryllium oxide, among others. The various components of heatsink 10 may be coupled using any suitable technique. In the embodiment of FIGS. 1 and 2, screws 60 are shown securing fan 45 to the upper plate. Similarly, pad 15 may be secured to base 20 via screws 65 and associated holes 67. If desired, these components may alternatively be coupled using any of a variety of different fasteners which can maintain these components in a fixed spatial relationship including, for example, thermal adhesives, welding, straps, clips, and the like. Conduit array 25 may be securely positioned between upper and lower plates 35 and 40 using, for example, any of the just-described coupling techniques.

Airflow through heatsink 10 may be accomplished either passively, or dynamically with the assistance of fan 45, for example. The fan may be powered by a suitable DC power source, the specifics of which are not essential. Addressing first the passive airflow aspect, it is to be understood that heatsink 10 typically experiences a temperature differential during use. That is, the components of the heatsink which are closest to the heat source will be hotter than components located further away from the heat source.

The various arrows of FIG. 1 show the general pathway of air flowing through the heatsink. Air from the surrounding atmosphere is shown entering the heatsink from the four sides of base 20. The air flows through channels 70 and 75, and flows upward through the conduits and associated apertures of pad 15, where it is convected into the atmosphere, away from the heatsink. It is to be understood that the just-described movement of air through the heatsink is accomplished without the need of a fan. This is because the heatsink is designed to cooperate with natural convective heat forces, as will now be described.

During operation, base 20 may be placed in contact with a heat source. This causes the base and pad to be heated by virtue of their thermal contact with the heat source. Because of the heat experienced by these components, air within the individual channels 70 and 75 of the base and the individual conduits 30 of the conduit array are also heated. In accordance with natural convective heat forces, heated air within the channels will rise and flow through apertures 50 of lower plate 40 and into individual conduits 30. Likewise, heated air within the conduits will rise and flow through apertures 50 of upper plate 35 where it dissipates into the surrounding atmosphere.

In a dynamic airflow process, optional fan 45 may be used to manipulate the airflow through heatsink 10. For example, in this embodiment, the fan may be used to force air away from the heatsink, and in particular, away from upper plate 35. The fan creates a negative pressure in an area between the bottom of the fan and the upper plate. This causes an increase in the rate of airflow through the various components of the heatsink. Note that since fan 45 is blowing air away from the heatsink, it is cooperating with, not against, the natural convective heat force which causes the heated air to rise.

In general, heatsink 10 may be sized to meet the cooling needs of a particular application. For instance, the length and width of base 20 and pad 15 may be such that they approximate the dimensions of the heat source with which they are thermally coupled. Alternatively, these components may be smaller or larger than the heat source, resulting in a corresponding relative decrease or increase in the amount of cooling provided to the heat source.

FIG. 3 is a top-view of pad 15, upper plate 35 having been omitted to show the spatial relationship of apertures 50 of the lower plate, relative to conduits 30 of the conduit array. This figure shows each aperture 50 of lower plate 40 relatively positioned within the opening of an associated conduit 30. In general, each aperture is sized to permit air to flow into an associated conduit. Conversely, apertures 50 of upper plate 35 (not shown in this figure) permit air to flow out of an associated conduit. Optimally, an aperture is coincident with the geometric center of its associated conduit, but this is not a requirement. As an example only, aperture 50 may have a diameter of about 0.052-0.825 inches. Typically, apertures formed in upper plate 35 are similarly orientated and similarly sized as those in the lower plate, but this is not a critical feature.

To increase the rate of airflow through the conduits, the diameter of the aperture may be increased. Alternatively or additionally, increased airflow may be accomplished by increasing the number of apertures associated with an individual conduit. Pad 15 may have the same or similar dimensions as base 20 (as discussed below), or the pad may be smaller than the base in length, width, or both.

If desired, the hexagonal structure of conduit 30 may alternatively be implemented using other geometries (for example, circular, oval, triangular, rectangular, pentagonal, a 7-sided or greater polygonal structure, and the like). In addition, conduit array 25 need not be formed from any particular number or arrangement of individual conduits. For example, conduit array 25 may be formed with as few as one or two individual conduits, or as many as 100-200, or more, conduits. Furthermore, the conduit array is shown having a number of individual conduits which are structurally attached, but the conduit array may alternatively be formed using conduits which are spaced at a distance relative to each other.

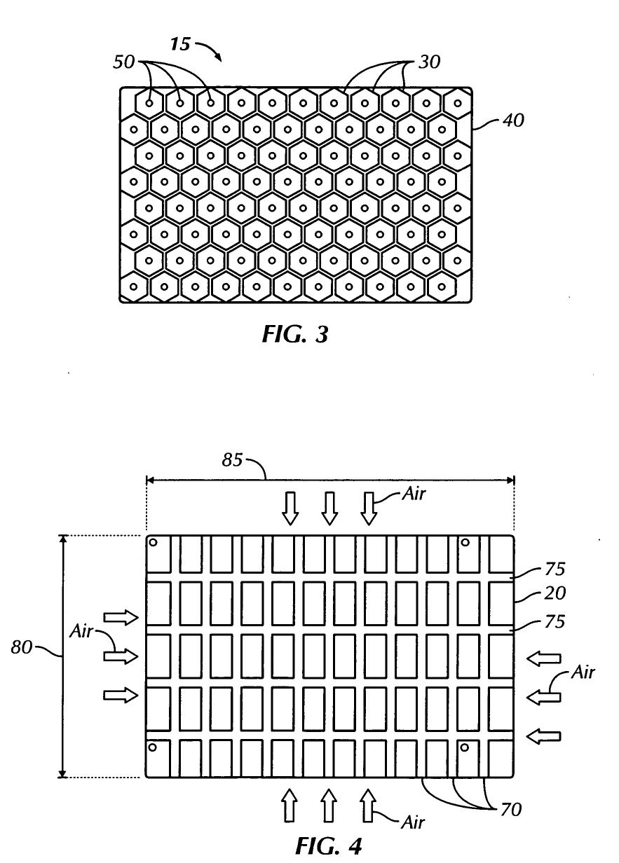

FIG. 4 is a top-view of base 20 showing a number of width-wise channels 70 and a number of length-wise channels 75. These channels permit air to flow from the surrounding atmosphere and into the heatsink along the four sides of base 20. By way of non-limiting example, base 20 may be sized so that it has a width 80 of about 2.25-3.75 inches, and a length 85 of about 2.25-4.25 inches.

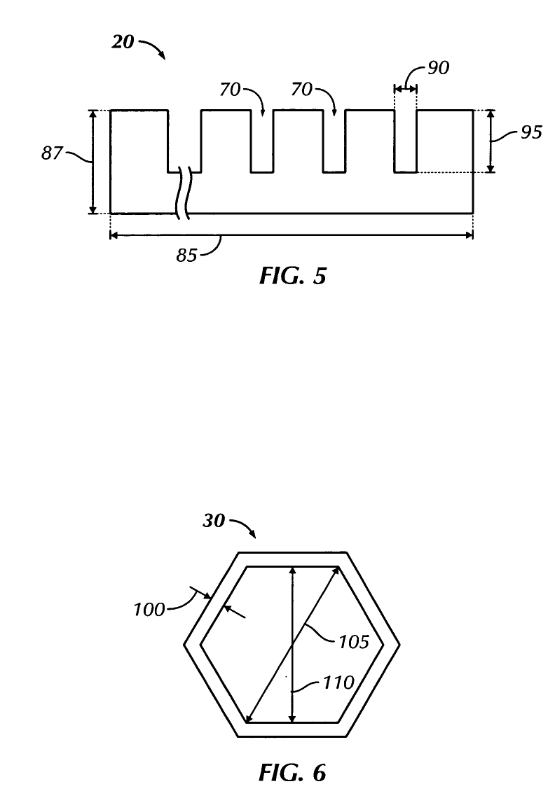

FIG. 5 is a partial side-view of base 20, which shows the relative width and height of the channels, as well as the height and length of the base. As noted above, no particular size or dimensions are required for these structures. By way of non-limiting example, base 20 may be sized so that it has an overall height 87 of about 0.250-1.025 inches. In addition, each width-wise channel 70 may have a width 90 of about 0.055-0.525 inches, and a height 95 of about 0.055-0.525 inches. The length-wise channels may be similarly dimensioned.

FIG. 6 is a top-view of an individual conduit which may be implemented as part of conduit array 25. As one example, conduit 30 may be formed as a hexagonal structure having a sidewall thickness 100 of about 0.005-0.020 inches, a major-axis 105 of about 0.225-0.275 inches, and a minor-axis 110 of about 0.175-0.222 inches.

FIG. 7 is a partial cross-sectional view of pad 15, showing several conduits 30 of the conduit array. Each conduit contains an open cavity bounded by walls 125. Adjacent conduits of the conduit array share common walls. The arrows depict air flowing upwardly through apertures 50 of lower plate 40, into the cavities of the various conduits, and ultimately exiting the pad via apertures 50 of upper plate 35. Again, this rising airflow is a result of natural convective heat forces, which may be augmented by the use of a fan.

In accordance with an embodiment, upper plate 35 may have a thickness 130 of about 0.002-0.075 inches, and conduit 30 may have a height 135 of about 0.250-1.025 inches. Lower plate 40 has a thickness 140, which typically approximates the thickness of the upper plate.

Pad 15 is shown having three individual structures which are thermally coupled, but the pad may be implemented as an integrated structure if so desired. In accordance with yet another alternative embodiment, FIG. 8 shows a partial cross-sectional view of pad 150. In this figure, each individual conduit 30 includes a separate upper plate 35 and a separate lower plate 40. The embodiment of FIG. 8 has a reduced overall size, while providing essentially the same cooling functionality as other embodiments. Pad 150 may be implemented in any of the heatsink embodiments disclosed herein.

Apertures 50 of the upper and lower plates of FIGS. 7 and 8 are shown having openings which are substantially smaller that the width of their associated conduits 30. If desired, the relative size of the apertures may be increased from that shown. Furthermore, the upper and lower plates may alternatively be omitted to meet the cooling requirements of a particular application.

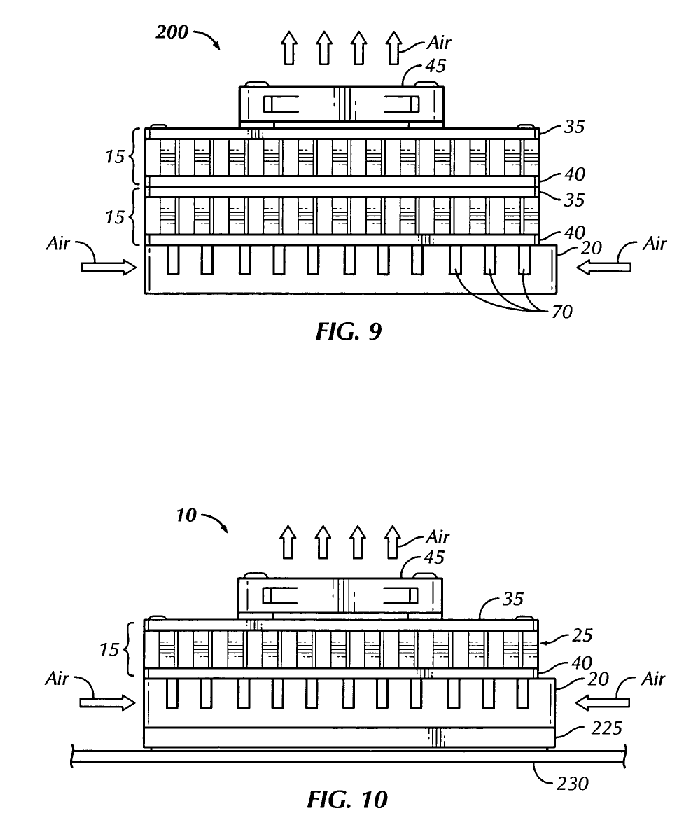

FIG. 9 is a side-view of heatsink 200, in accordance with an alternative embodiment of the present invention. In contrast to heatsink 10 of FIG. 1, heatsink 200 includes two pads positioned above the base. Specifically, heatsink 200 includes a first pad 15 which is thermally coupled to base 20, and a second pad 15 which is thermally coupled to the first pad. To facilitate airflow through the heatsink, the apertures of lower plate 40 of the second pad should substantially coincide with the apertures of upper plate 35 of the first pad. The use of two pads increases the overall surface area of the heatsink, resulting in increased cooling to the heat generating device (not shown in this figure) with which the heatsink is associated. If desired, heatsink 200 may alternatively include three or more separate pads to provide additional cooling.

The arrangement of FIG. 9 permits the construction of differently sized heatsinks using a single type of material; namely, pad 15. There is no need to utilize pads of different thickness. As such, the manufacturing process is simplified resulting in overall cost savings in the production of the heatsink.

FIG. 10 is a side-view of heatsink 10 cooling a heat generating device 225 in accordance with an embodiment of the present invention. Examples of heat generating devices which may be cooled by the heatsink include a central processing unit (CPU), integrated circuits, power supplies, power transistors, voltage regulators, and microprocessors, among others. For ease of discussion, further description of FIG. 10 will be made with reference to the heat generating device implemented as a CPU.

Heatsink 10 is shown thermally coupled to a substantially planar top surface of CPU 225. This coupling may be achieved using any suitable fastener which maintains these components in a fixed spatial relationship including, for example, thermal adhesives, welding, straps, clips, and the like. CPU 225 in turn is coupled to printed circuit board (PCB) 230. When the CPU is in use, it generates more heat than it can dissipate alone. A portion of the heat which accumulates on the top surface of the CPU is absorbed into base 20 by virtue of the thermal contact between the CPU and the base. Thus, the temperature of the CPU is reduced by the absorption of heat into the base.

Some of the heat absorbed by the base may be convected directly to the surrounding atmosphere, while a significant portion of this heat is absorbed by the structures of pad 15. As base 20 and pad 15 become heated, air within the individual channels 70 and 75 of the base, and the individual conduits 30 of the conduit array, are also heated. Consequently, natural convection causes the heated air within the channels to rise and flow through apertures 50 of lower plate 40 and into individual conduits 30. Likewise, heated air within the conduits may also rise and flow through apertures 50 of upper plate 35 where it dissipates into the surrounding atmosphere. The various arrows of FIG. 10 show the general pathway of air flowing through the heatsink. As previously noted, fan 45 may optionally be implemented to enhance the rate of airflow through the various structures of the heatsink.

The rate of heat transfer between CPU and the base and pad is directly proportional to the temperature difference between CPU 225, and the base and pad. Accordingly, a higher rate of heat transfer from the CPU may be accomplished by cooling the base and pad. In accordance with various embodiments, the base and pad may be cooled by the flowing air, thereby increasing the heat transfer between these components and the CPU.

Base 20 and pad 15 have been shown and described as having substantially planar surfaces at their respective interfacing regions. That is, the bottom surface of the base is substantially planar to facilitate the thermal coupling with CPU 225. Similarly, the top surface of base 20 and the bottom surface of pad 15 are also substantially planar. However, the illustrated embodiments are not so limited and these structures may alternatively be formed with non-planar interfacing regions if so desired.

While the invention has been described in detail with reference to disclosed embodiments, various modifications within the scope of the invention will be apparent to those of ordinary skill in this technological field. It is to be appreciated that features described with respect to one embodiment typically may be applied to other embodiments. Therefore, the invention properly is to be construed only with reference to the claims.

What is claimed is:

1. A heatsink for removing heat from a heat source, said heatsink comprising:
a base comprising an airflow passage and adapted to contact at least a portion of said heat source; and
a pad in thermal contact with said base, said pad comprising an array of conduits positioned over said airflow passage and permitting air to flow from said airflow passage, through said array of conduits.

2. The heatsink according to claim 1, wherein said airflow passage of said base includes:
a plurality of length-wise channels extending across a length of said base; and
a plurality of width-wise channels extending across a width of said base.

3. The heatsink according to claim 1, wherein said airflow passage of said base is defined by a plurality of air channels.

4. The heatsink according to claim 1, further comprising:
a fan associated with a top surface of said pad, said fan adapted to direct air away from said pad.

5. The heatsink according to claim 1, further comprising:
a plurality of pads in thermal contact with said base, wherein each of said plurality of pads comprise an array of conduits positioned over said airflow passage, wherein vertically adjacent conduits of said pads are substantially coincident and permit said air to flow from said airflow passage, through said array of conduits of said plurality of pads.

6. The heatsink according to claim 1, further comprising:
upper and lower plates having said array of conduits positioned therebetween; and
apertures formed in said upper and lower plates.

7. The heatsink according to claim 6, wherein each of said apertures formed in said upper and lower plates are coincident with an associated conduit of said array of conduits.

8. The heatsink according to claim 6, wherein each of a plurality of said apertures formed in said upper and lower plates define an opening which is smaller than a diameter of an associated conduit of said array of conduits.

9. The heatsink according to claim 6, wherein each of a plurality of said apertures formed in said upper and lower plates define an opening which is substantially the same as a diameter of an associated conduit of said array of conduits.

10. The heatsink according to claim 1, further comprising:
an upper plate positioned within each of said array of conduits;
a lower plate positioned within each of said array of conduits; and
at least one aperture formed in each of said upper and lower plates.

11. The heatsink according to claim 1, wherein each of said array of conduits are structured as a hexagonal conduit.

12. The heatsink according to claim 1, wherein each of said array of conduits are structured using a geometry selected from the group consisting of circular, oval, triangular, rectangular, pentagonal, and N-sided polygonal in which N is greater than six.

13. The heatsink according to claim 1, wherein said base and said pad are formed from a thermally conductive material selected from the group consisting of aluminum, copper, copper-tungsten alloy, aluminum nitride, and beryllium oxide.

14. The heatsink according to claim 1, wherein said base and said pad are coupled using a thermal adhesive.

15. The heatsink according to claim 1, wherein said heat source is selected from the group consisting of an integrated circuit, a power supply, a power transistor, a voltage regulator, a central processing unit (CPU), and a microprocessor.

16. A circuit board assembly, comprising:
a circuit board;
an electronic component coupled to said circuit board;
a heatsink for removing heat from said electronic component, said heatsink comprising:
a base comprising an airflow passage and adapted to contact at least a portion of said electronic component; and <a pad in thermal contact with said base, said pad comprising an array of conduits positioned over said airflow passage and permitting air to flow from said airflow passage, through said array of conduits.

17. A heatsink for removing heat from a heat source, said heatsink comprising:
receiving means for receiving air from atmosphere externally located relative to said heatsink; and
directing means for convectively directing said air from said receiving means through an array of conduits.

18. The heatsink according to claim 17, further comprising:
means for blowing said air away from said heatsink.

19. An apparatus for removing heat from a heat source, said apparatus comprising:
a base comprising airflow passages and adapted to contact at least a portion of said heat source;
upper and lower plates, wherein said lower plate thermally contacts said base;
apertures formed in said upper and lower plates; and
an array of conduits positioned between said upper and lower plates, wherein each conduit of said array of conduits is associated with at least one of said apertures formed in each of said upper and lower plates.
